(19) United States
(12) Patent Application Publication
(10) Pub. No.: US 2009/0132883 A1
(43) Pub. Date: May 21, 2009

(54) TEST CIRCUIT

(75) Inventor: Koji KANBA, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kawasaki (JP)

(21) Appl. No.: 12/266,141

(22) Filed: Nov. 6, 2008

(30) Foreign Application Priority Data
Nov. 16, 2007 (JP) 2007-297616

(51) Int. Cl. G01R 31/3177; G06F 11/25

(52) U.S. Cl. 714/733; 714/E11.155

(57) ABSTRACT

A test circuit includes a plurality of circuit blocks having a same circuit construction and a same function, a plurality of internal test circuits each corresponding to a different one of the plurality of circuit blocks, an OR circuit which outputs a logical sum result of a test result output by each of the plurality of circuit blocks as a first result signal, an AND circuit which outputs a logical product result of the test result output by each of the plurality of circuit blocks as a second result signal, and a decision circuit which outputs a consistent comparison result between the first result signal and the second result signal as a final result signal.

### BACKGROUND

1. Field of the Invention

The present invention relates to a test circuit, in particular a test circuit for a plurality of circuit blocks having the same circuit structure and the same function.

2. Description of Related Art

As semiconductor devices have been equipped with more functions and have become larger in scale in recent years, the amount of test patterns that are used to test the internal circuits have also become enormous. Furthermore, the number of test terminals that are used to output test results from a test circuit has also increased with the increase in the scale of the test circuit. Accordingly, Japanese Unexamined Patent Application Publication No. 2004-69642 (Sakai et al.) discloses a technique to reduce the number of test terminals.

FIG. 6 shows a block diagram of a semiconductor device 100 disclosed in Sakai et al. As shown in FIG. 6, the semiconductor device 100 has circuit blocks (logic circuits A-C), each of which has the same function and outputs output data DOUT based on input data DIN, an OR circuit 101 to output the logical OR operation result of test result signals TDOa-TDOc output from the logic circuits A-C as a first result signal X, and an AND circuit 102 to output the logical AND operation result of the test result signals TDOa-TDOc as a second result signal Y. In this circuit, since the plurality of circuit blocks have the same function, the test patterns for these circuit blocks are also the same. In addition, the test results obtained from those test patterns are also the same when these circuit blocks work properly. Therefore, common input data DIN and common test control signals (including a scanning clock signal SCK, a scan mode control signal SMC, and test pattern data TPD) are input to the logic circuits A-C.

Accordingly, the semiconductor device 100 determines the test result by carrying out the logical OR operation and the logical AND operation of the test result signals TDOa-TDOc output from these three circuit blocks. In this manner, the semiconductor device 100 can make a decision on the test result signals output from the three circuit blocks with the two test terminals, and thereby reducing the number of test terminals.

### SUMMARY

However, there has been a problem that the semiconductor device 100 disclosed in Sakai et al. still needs two test terminals to make a decision on the test result, and therefore the number of test terminals has not been sufficiently reduced.

An exemplary aspect of the present invention is a test circuit includes a plurality of circuit blocks having a same circuit construction and a same function, a plurality of internal test circuits each corresponding to a different one of the plurality of circuit blocks, an OR circuit which outputs a logical sum result of a test result output by each of the plurality of circuit blocks as a first result signal, an AND circuit which outputs a logical product result of the test result output by each of the plurality of circuit blocks as a second result signal, and a decision circuit which outputs a consistent comparison result between the first result signal and the second result signal as a final result signal.

A test circuit in accordance one exemplary embodiment of the present invention has a decision circuit to output a matching comparison result of a first result signal and a second result signal as a final result signal. In this manner, it enables to output a plurality of test result signals output from a plurality of circuit blocks as one final result signal.

A test circuit in accordance one exemplary embodiment of the present invention can significantly reduce the number of test terminals necessary to obtain test results.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram of a test circuit in accordance with a first exemplary embodiment of the present invention;

FIG. 2 is a block diagram showing the structure of a logic circuit in accordance with the first exemplary embodiment of the present invention;

FIG. 3 is a block diagram showing another example of the structure of the logic circuit in accordance with the first exemplary embodiment of the present invention;

FIG. 4 is a table showing logical values for each signal in the test circuit in accordance with the first exemplary embodiment of the present invention;

FIG. 5 is a block diagram of a test circuit in accordance with a second exemplary embodiment of the present invention; and

FIG. 6 is a block diagram of a test circuit of a semiconductor device in the related art.

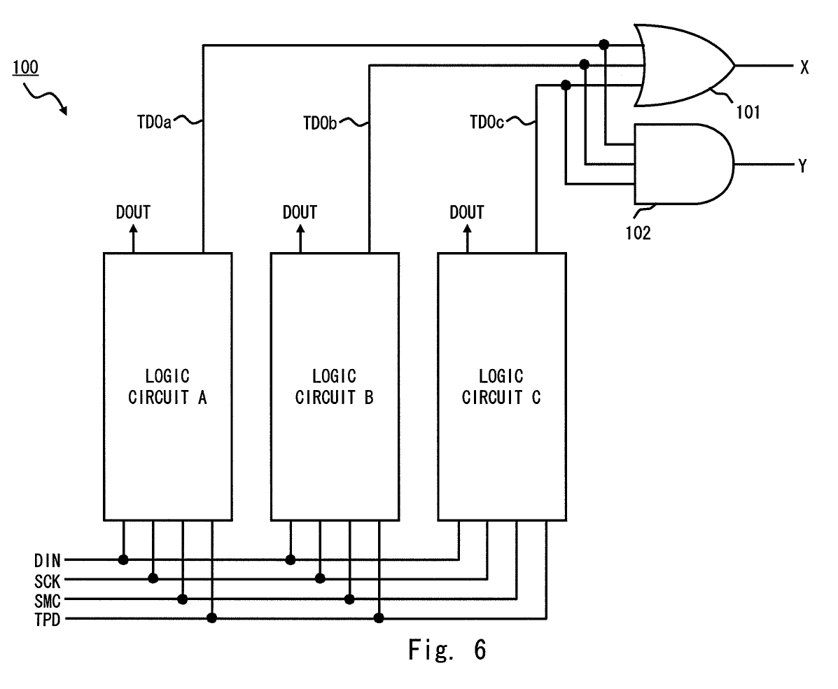

### DETAILED DESCRIPTION OF THE EXEMPLARY EMBODIMENTS

### First Exemplary Embodiment

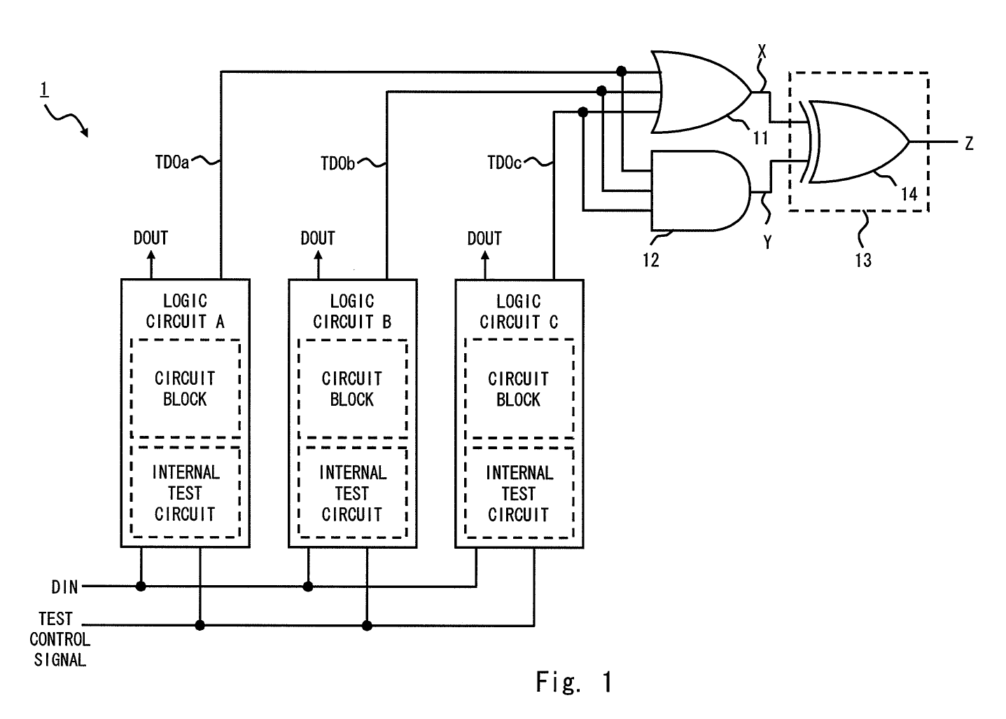

Embodiments of the present invention are explained hereinafter with reference to the drawings. FIG. 1 shows a block diagram of a test circuit portion of a semiconductor device 1 in accordance with this exemplary embodiment of the present invention. As shown in FIG. 1, the test circuit in accordance with this exemplary embodiment has a plurality of logic circuits A-C, a logical sum circuit (OR circuit) 11, a logical multiplication circuit (AND circuit) 12, and a decision circuit 13. Each of the plurality of logic circuits A-C has a circuit block and an internal test circuit. All of the circuit blocks have the same circuit structure and function, and all of the internal test circuits have the same circuit structure and function. The details of the circuit block and the internal test circuit are explained later.

Common input data DIN and common test control signal(s) are input to the plurality of logic circuits A-C. Incidentally, the specific signal(s) included in the test control signal(s) is different depending on the structure of the internal test circuit. Furthermore, each of the plurality of logic circuits A-C outputs an output data DOUT and test result signals TDOa-TDOc. The output data DOUTs are output to other circuits (not shown).

The test result signals TDOa-TDOc are input to the OR circuit 11. Then, the OR circuit 11 outputs the logical OR operation result of the test result signals TDOa-TDOc as a first result signal X. The test result signals TDOa-TDOc are also input to the AND circuit 12. Then, the AND circuit 12 outputs the logical AND operation result of the test result signals TDOa-TDOc as a second result signal Y. The decision circuit 13 outputs the matching comparison result between the first result signal X and the second result signal Y as a final result signal Z. In this exemplary embodiment of the present invention, the decision circuit 13 realizes the matching comparison operation by an exclusive-OR circuit (XOR circuit) 14 that carries out an exclusive-OR operation of two input signals.

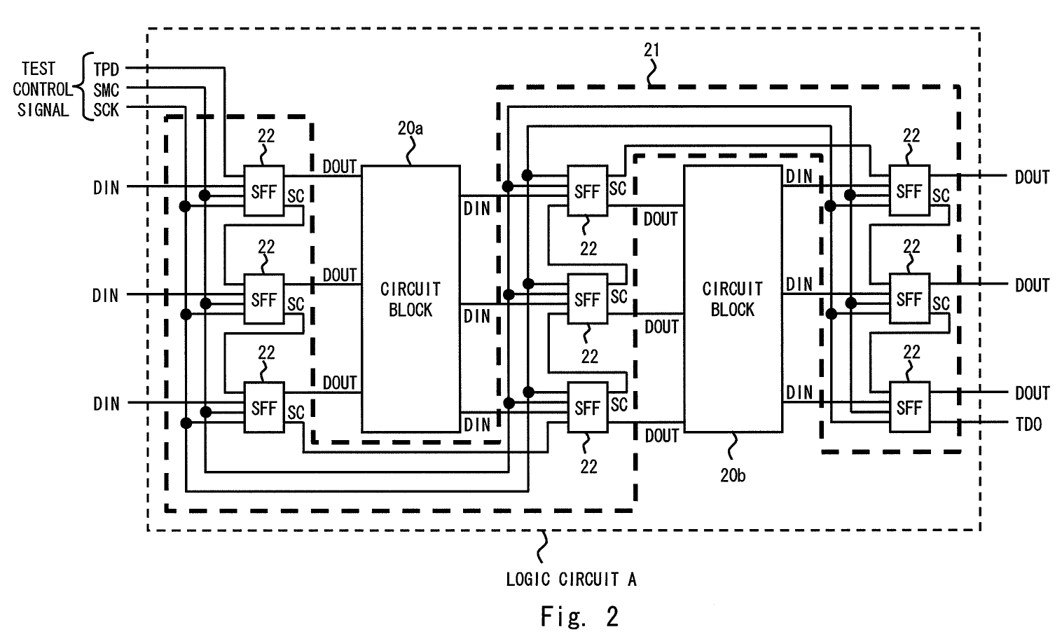

The details of the circuit blocks and the test circuits contained in the logic circuits A-C are explained hereinafter. All of the logic circuits A-C have the same circuit structure and the same function. Accordingly, the structure of these logic circuits is explained by taking the logic circuit A as an example hereinafter. FIG. 2 shows a block diagram showing one example of the structure of the logic circuit A. The example shown in FIG. 2 uses a scan chain circuit as the internal test circuit. As shown in FIG. 2, the logic circuit A has a plurality of circuit blocks 20a and 20b, and the scan chain circuit 21. When a scan chain circuit is used as the internal test circuit, test pattern data TPD, a scan mode control signal SMC, and a scanning clock signal SCK are input as the test control signals.

The circuit blocks 20a and 20b process input data DINs and output output data DOUTs. The scan chain circuit 21 includes a plurality of serially-connected scanning flip-flops 22 (shown as “SFF” in the figure). Furthermore, the scan chain circuit 21 is configured so as to be connected to the inputs and the outputs of the circuit block 20a and the circuit block 20b. The scanning flip-flop 22 located at the first stage changes between a state where it outputs the input data as the output data DOUT and a state where it handles the test pattern data TPD as a shift data SC that is input to the scanning flip-flop 22 at the next stage based on the logical value of the scan mode control signal SMC. Each of the scanning flip-flops 22 located at the second stage and subsequent stages changes between a state where it outputs the input data as the output data DOUT and a state where it handles the shift data SC from the scanning flip-flop 22 at the preceding stage as the shift data SC that is input to the scanning flip-flop 22 at the next stage based on the logical value of the scan mode control signal SMC. Incidentally, the shift data from the scanning flip-flop 22 located at the last stage is output as the test result signal TDO. Furthermore, the scanning flip-flops 22 take in data to be input in response to the rising edge or the falling edge of the scanning clock signal SCK.

The operation of the scan chain circuit 21 is explained hereinafter. In the normal operation mode where the scan mode control signal SMC is at a low level, the scan chain circuit 21 outputs the input data to the circuit blocks 20a and 20b. On the other hand, in the scan mode, the scan mode control signal SMC is firstly brought to a high level, and then all of the scanning flip-flops 22 are set with the test pattern data TPDs in response to the scanning clock signal SCK. (This action is called “first shift action”.) Next, the scan mode control signal SMC is brought to a low level, so that the test pattern data TPDs set in the flip-flops are input to the circuit blocks 20a and 20b. (This action is called “launch action”.) Then, the outputs from the circuit blocks 20a and 20b are taken into the scanning flip-flops 22 in response to the scanning clock signal SCK. (This action is called “capture action”.) Subsequently, the scan mode control signal SMC is brought to a high level, and the data that are taken into the scanning flip-flops 22 are successively output as the test result signal TDO in response to the scanning clock signal SCK. (This action is called “second shift action”.)

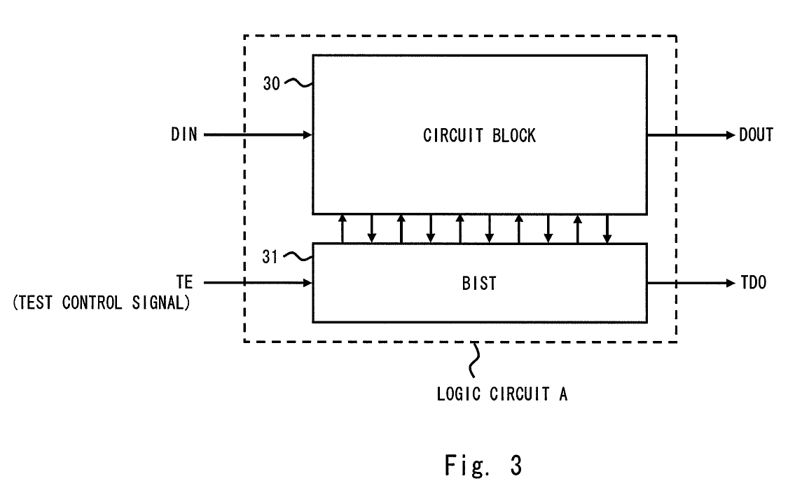

Furthermore, FIG. 3 shows a block diagram showing another example of the structure of the logic circuit A. The example shown in FIG. 3 uses a BIST (Built In Self Test) circuit as the internal test circuit. As shown in FIG. 3, the logic circuit A has a circuit block 30 and a BIST circuit 31. When a BIST circuit is used as the internal test circuit, a test enable signal is input as the test control signal. The circuit block 30 processes input data DIN and outputs output data DOUT. The BIST circuit 31 has a test pattern generator that generates test pattern data TPD for the circuit block 30 within it. Furthermore, the BIST circuit 31 tests various functions of the circuit block 30 in accordance with the logic level of the test enable signal, and outputs the test results as the test result signal TDO. In this exemplary embodiment of the present invention, all the BIST circuits 31 contained in the logic circuits A-C generate the same test pattern data TPD.

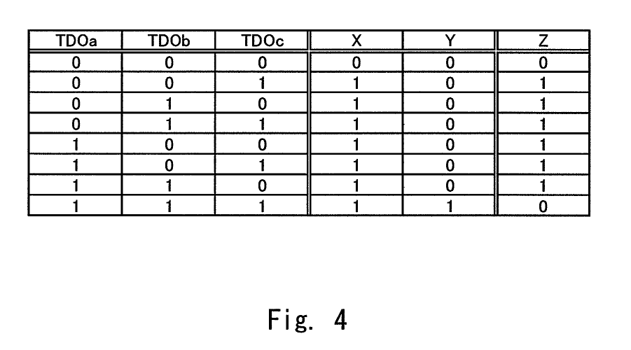

Next, the operation of a test circuit in accordance with this exemplary embodiment of the present invention is explained hereinafter. FIG. 4 shows the relations among the test result signals TDOa-TDOc, the first result signal X, the second result signal Y, and the final result signal Z in a test circuit in accordance with this exemplary embodiment of the present invention. In this exemplary embodiment, the logic circuits A-C have the same circuit structure and the same function, and therefore the same test pattern data TPD is supplied to the circuit blocks of the logic circuits A-C. Therefore, when these circuit blocks have no malfunction, all of the test result signals TDOa-TDOc have the same logical value. On the other hand, when any one of the circuit blocks has a malfunction, they output test result signals having different logical values.

In the example shown in FIG. 4, the combinations of the test result signals TDOa-TDOc in which they are all “0s” or “1s” represents the case where there is no malfunction in the circuit blocks. In this point, both of the first result signal X and the second result signal Y become “0s” or “1s”. Therefore, the final result signal Z that is output from the decision circuit 13 becomes “0”.

On the other hand, when any one of the circuit blocks has a malfunction, one of the test result signals TDOa-TDOc becomes “0” or “1”. Therefore, the first result signal X, which is the logical OR operation result of the test result signals TDOa-TDOc, becomes “1”, and the second result signal Y, which is the logical AND operation result of the test result signals TDOa-TDOc, becomes “0”. As a result, since the first result signal X and the second result signal Y do not match with each other, the decision circuit 13 outputs “1” as the final result signal Z.

That is, the final result signal Z becomes “0” when there is no malfunction in the circuit blocks, and the final result signal Z becomes “1” when there is a malfunction in the circuit blocks in the test circuit in accordance with this exemplary embodiment of the present invention. In other words, the test circuit in accordance with this exemplary embodiment can indicates the presence of a malfunction in the circuit blocks with a 1-bit value.

As can be seen from the above explanations, a test circuit in accordance with this exemplary embodiment of the present invention can provide test results for a plurality of logic circuits having the same circuit structure and the same function with a single final result signal Z. That is, a test circuit in accordance with this exemplary embodiment can provide the test results for a plurality of logic circuits having the same circuit structure and the same function with a single test result acquisition test terminal. Therefore, it can reduce the number of test terminals that are used to obtain the test results in a semiconductor device. The advantageous effect by the reduction of the test terminals becomes more prominent with the increase in the number of the test result signals TDOs. In particular, it will become effective when the number of the test result signals output from the logic circuits is at least three.

Furthermore, a test circuit in accordance with this exemplary embodiment of the present invention can also reduce the amount of test pattern data for verification. For example, since the semiconductor device 100 disclosed in Sakai et al. does not have the decision circuit 13, the values of the first result signal X and the second result signal Y vary depending on the logical values of the test result signals TDOa-TDOc output from the logic circuits A-C. Therefore, the test pattern data for verification must be generated in accordance with the changes of the logical values of the test result signals TDOa-TDOc. In contrast to this, the test circuit in accordance with this exemplary embodiment of the present invention can determine the presence of a malfunction in the circuit blocks with a 1-bit value. That is, the only necessary test pattern data for verification is a single value of “0”. That is, the data amount of the test pattern data for verification does not increase depending on the data length and the number of the types of the test pattern data TPD in the test circuit in accordance with this exemplary embodiment of the present invention. Furthermore, it can also reduce the time necessary to generate and verify the test pattern data for verification.

### Second Exemplary Embodiment

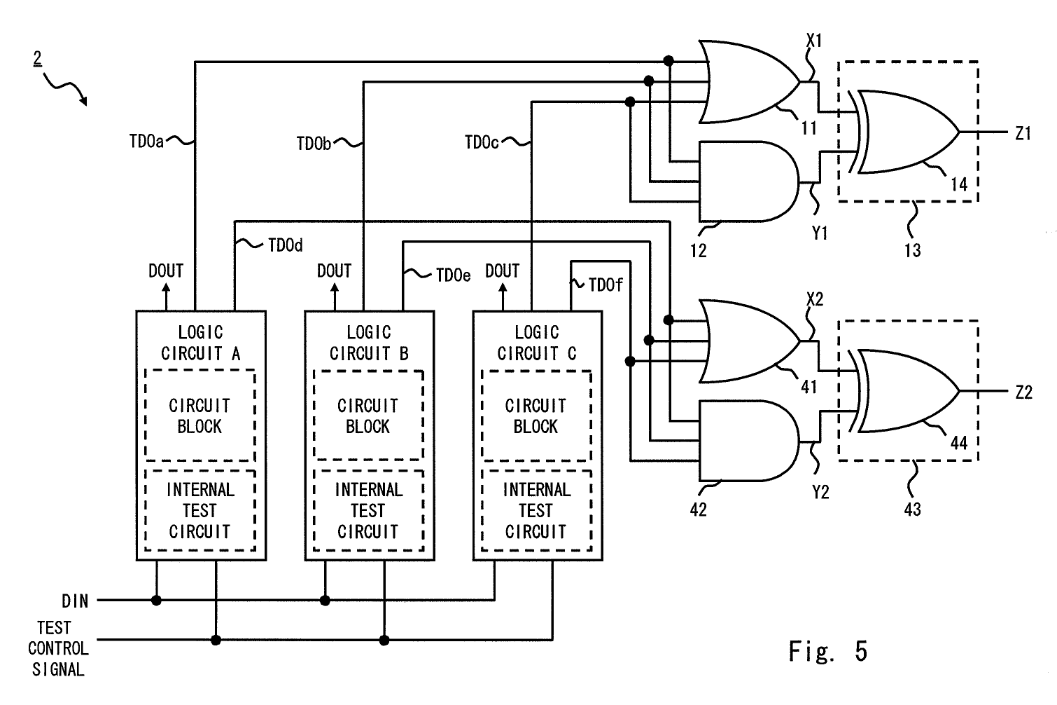

FIG. 5 shows a block diagram of a test circuit in accordance with a second exemplary embodiment of the present invention. As shown in FIG. 5, each of the logic circuits A-C outputs two test result signals in the second exemplary embodiment. For example, the logic circuit A outputs test result signals TDOa and TDOd; the logic circuit B outputs test result signals TDOb and TDOe; and the logic circuit C outputs test result signals TDOc and TDOf. The test result signals TDOd-TDOf may be output from a different internal test circuit from the internal test circuit that outputs the test result signals TDOa-TDOc, or may be output from the same internal test circuit. Incidentally, all of the test result signals TDOa-TDOc have the same logical values when the corresponding circuit blocks have no malfunction, and all of the test result signals TDOd-TDOf have the same logical values when the corresponding circuit blocks have no malfunction.

The test circuit in accordance with the second exemplary embodiment of the present invention has an OR circuit 41, an AND circuit 42, and a decision circuit 43, all of which are provided for the test result signals TDOd-TDOf, as well as the OR circuit 11, the AND circuit 12, and the decision circuit 13, all of which are provided for the test result signals TDOa-TDOc The connection and the operation of the OR circuit 41, the AND circuit 42, and the decision circuit 43 are substantially the same as those of the OR circuit 11, the AND circuit 12, and the decision circuit 13, and therefore the explanations of them are omitted as appropriate. Incidentally, the decision circuit 43 makes a matching comparison between a first result signal X2 and a second result signal Y2 by an exclusive-OR circuit (XOR circuit) 44, and outputs a final result signal Z2. Furthermore, the signs X1, Y1, and Z1 are used as the corresponding signs to the first result signal X and the second result signal Y and the final result signal Z respectively in FIG. 5.

As can be seen from the above explanations, even when there are a plurality of pairs of test result signals, each of which has the same result within its respective pair when there is no malfunction in the corresponding circuit blocks, the only necessary requirement for the test circuit in accordance with one exemplary embodiment of the present invention is that the same number of test result verification test terminals should be provided as the number of the pairs of test result signals that have the same result. That is, even when the number of pairs of test result signals that have the same result is increased, the present invention can prevent the test circuit from increasing in the number of the test terminals. The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A test circuit comprising:
a plurality of circuit blocks having a same circuit construction and a same function;
a plurality of internal test circuits each corresponding to a different one of the plurality of circuit blocks;
an OR circuit which outputs a logical sum result of a test result output by each of the plurality of circuit blocks as a first result signal;
an AND circuit which outputs a logical product result of the test result output by each of the plurality of circuit blocks as a second result signal; and
a decision circuit which outputs a consistent comparison result between the first result signal and the second result signal as a final result signal.

2. The test circuit according to claim 1, wherein the decision circuit includes a XOR circuit which outputs an exclusive OR operation result between the first result signal and the second result signal as the final result signal.

3. The test circuit according to claim 1, wherein the plurality of the internal test circuits are scan chain circuits corresponding to each circuit block and a same test pattern is input to each of the plurality of the internal test circuits.

4. The test circuit according to claim 3, wherein the same test pattern includes test pattern data, a scan mode control signal, and a scan click signal.

5. The test circuit according to claim 1, wherein the plurality of the internal test circuits are Built In Self Test (BIST) circuits corresponding to each circuit block and generate a same test pattern.

6. The test circuit according to claim 1, wherein each circuit block outputs at least two test result signals, each corresponding to a different set of test result signals of the plurality of circuit blocks, and a circuit set comprising the OR circuit, the AND circuit and the decision circuit is provided for each set of test result signals.

7. The test circuit according to claim 6, wherein the internal test circuit outputs the at least two test result signals.

8. The test circuit according to claim 6, wherein each of plurality circuit blocks includes at least two internal test circuits, the at least two internal test circuit each output one of the at least two test result signals, and the circuit set comprising the OR circuit, the AND circuit and the decision circuit is provided for each of the at least two internal test circuits.

9. The test circuit according to claim 6, wherein each circuit set corresponds to one test result signal of each of the plurality of circuit blocks, the set of test result signals comprising the one test result signal of each of the plurality of circuit blocks.

10. The test circuit according to claim 8, wherein each circuit set corresponds to one test result signal of each of the plurality of circuit blocks, the set of test result signals comprising the one test result signal of each of the plurality of circuit blocks.
